(19) United States
(12) Patent Application Publication
(10) Pub. No.: US 2018/0366768 A1
(43) Pub. Date: Dec. 20, 2018

(54) Porous Silicon One-Wafer Battery with Voltage Enhancement by Internal Field

(71) Applicant: Neah Power Systems, Inc., Bothell, WA (US)

(72) Inventor: Slobodan Petrovic, Kirkland, WA (US)

(21) Appl. No.: 16/011,655

(22) Filed: Jun. 19, 2018

Related U.S. Application Data
(60) Provisional application No. 62/521,532, filed on Jun. 19, 2017.

(51) Int. Cl. H01M 10/052; H01M 10/0562; H01M 10/058; H01M 4/505; H01M 4/525; H01M 4/58; H01M 2/08; H01M 10/44; H01L 31/04

(52) U.S. Cl. CPC H01M 10/052; H01M 10/0562; H01M 10/058; H01M 4/505; H01M 2004/021; H01M 4/5825; H01M 2/08; H01M 10/44; H01L 31/04; H01M 4/525

(57) ABSTRACT

The invention provides methods, apparatuses, and systems that may provide an improved battery, wherein the battery includes a wafer with matrix design which provides greatly simplified construction of cells, increased energy density and power density, elimination of a separator, completely sealed cells, increased safety, and many more features. In some embodiments, to a wafer battery such as a one-wafer battery wherein the performance is increased by incorporating a p-n-junction in each pore of a wafer matrix, thus creating a porous silicon one-wafer battery with voltage enhancement by internal field.

This application claims priority from at least U.S. Provisional Patent Application 62/521,532 filed on Jun. 19, 2017 entitled “Porous Silicon One-Wafer Battery with Voltage Enhancement by Internal Field” which applications may be incorporated herein by reference in its entirety for all purposes.

### FIELD OF TECHNOLOGY

This disclosure relates generally to batteries. In one example embodiment, to methods, apparatus, and systems to an improved battery with a one-wafer design and at least voltage enhancements by internal fields in addition to other improvements.

### BACKGROUND

Within many fields, batteries are used to provide power to devices. In the last decade the average device, whether it be in consumer, commercial, military, industrial or other applications, have evolved in functionality, requiring larger capacity and higher power, faster discharge and charge rates, and improved safety. It may expected that in the near future electronic devices are only going to become more energy demanding. Thus there is a need for improved batteries at every scale.

Any improvement in efficiency, safety, energy density, charge and discharge rates, and manufacturing costs is greatly desired. Throughout the past decades, batteries have evolved from lead acid or nickel-based batteries to lithium ion. Lithium ion batteries today offer high performance, with superior energy density and specific energy compared to previous battery types. However, there are many drawbacks and design limitations in the prior art that have a need to be improved.

Thus, there may be a need for an improved battery that provides an economical and easy to produce structure, with improvements in at least safety, energy density, discharge and charge rates as well as other aspects which may further meet the demand of users today and in the future.

### SUMMARY

Disclosed may be methods, apparatus, and systems that may provide an improved battery.

The present invention may provide a battery which can include features such as at least providing for a one or more wafer battery. The one wafer design may include the ability for many improvements over prior art including at least providing for greatly simplified construction of the cell, increased energy density and power density, elimination of a separator, completely sealed cells, increased safety, and many more.

Additionally, the battery can include an enhancement of the performance by incorporating a p-n-junction in the present invention battery. This may create an electrical field that enhances transport of electrons towards the electrode current collector and improves performance by adding an additional voltage to the battery during the discharge.

The present invention battery may include at least a completely new battery packaging where the battery itself may be encapsulated during manufacturing such as by simple compression molding with a plastic compound. This may allow thinner packaging and require less assembly components than other prior arts.

Another aspect may be that a photovoltaic effect can be included within the silicon battery structure by having built-in p-n-junction, where it can be used to at least partially charge the battery in the absence of a power supply or to create additional voltage during battery discharge.

The p-n junction as well as the battery material itself may also include or be designed such that improved charging rate and higher output may be realized. This may include at least for instance the substrate for the lithium metal battery may be porous silicon where this substrate can perform as an electrode for lithium metal battery.

In a two-electrode cell, a special feature may be implemented wherein the surfaces of electrodes facing each other and the separator are passivated with insulating material to prevent build-up of lithium dendrites during charging. In case of silicon wafers as electrodes, the openings of the pores in wafers that face the separator and each other may be passivated with a non-conductive coating to prevent build-up of dendrites on the electrode surfaces facing each other. Only the opposite sides of the wafers may be covered with conductive coating and the coating extends into the first part of the pores. In case of dendrite build-up on those surfaces or inside the pores the dendrites will keep bouncing inside the pores and may not protrude all the way out and towards the separator, which could cause an electrical short with the opposite electrode.

In a one-wafer battery a similar principle is used. The silicon may be covered with metal in the electrode areas towards the pore openings and with insulator in the middle of the pores, between the electrodes. This may enhance element capable of “moving” electrons in the direction of the voltage difference during the discharge. The pn junction formed presents an effective addition to electron flow and may aid in charging and discharge abilities.

In summary, the present invention may provide for an improved battery which has reduced manufacturing costs and complexity as well as better packaging and space limitation while also including higher energy density, higher charge and discharge rates, improved safety as well as other features such as a photovoltaic ability.

The methods and systems disclosed herein may be implemented in any means for achieving various aspects. Other features may be apparent from the accompanying drawings and from the detailed description that follows.

### BRIEF DESCRIPTION OF THE DRAWINGS

Example embodiments may be illustrated by way of example and may be not limited to the figures of the accompanying drawings, in which, like references indicate similar elements.

FIGS. 1A and 1B may be a cross-section view of one example embodiment of one pore in a complete “one-wafer battery”.

FIG. 2 may be a cross-section view of one example embodiment of a compression molded package of the one-wafer batter with one pore.

FIGS. 3A and 3B may be a cross-section view of one example embodiment of a battery with transparent window and depiction of the photovoltaic effect for performance enhancement.

FIG. 4 may be a cross-section view of one example embodiment of the movement of charge (e− and Li+) in the discharge process of the one wafer battery.

FIG. 5 may be a process diagram of one example embodiment of a p-type silicon wafer to porous silicon.

FIG. 6 may be a process diagram and cross-section view of one example embodiment of passivation and partial removal of passivation.

FIG. 7 may be a process schematic and cross-section view of one example embodiment of the present invention.

FIG. 8 may be a process schematic and cross-section view of one example embodiment of metallization of the pores and the wafer face.

FIG. 9 may be a process schematic and cross-section view of one example embodiment of a partial electrolyte fill.

FIG. 10 may be a process schematic and cross-section view of one example embodiment of synthesis of cathode active material inside the pore.

FIG. 11 may be a cross-section view of one example embodiment of metallization of the cathode side.

FIG. 12 may be a process diagram of one example embodiment of an overview of the fabrication of the present invention.

FIG. 13 may be a process diagram of one example embodiment of an overview of the fabrication of the present invention.

FIG. 14 may be a process diagram of one example embodiment of an overview of the fabrication of the present invention.

Other features of the present embodiments may be apparent from the accompanying drawings and from the detailed description that follows.

### DETAILED DESCRIPTION

Disclosed may be methods, apparatus, and systems that may provide for an improved lithium battery which has reduced manufacturing costs and complexity as well as better packaging while also including higher energy density, specific energy, charge and discharge rates as well as other features such as a photovoltaic ability etc.

Neah Power Systems has previously filed U.S. patent application Ser. No. 14/952,237 for use of porous silicon in lithium batteries entitled: “Device and related method for assembling a battery using porous, structured silicon.” This invention introduces an entirely new concept using porous silicon and may be designed for high-output lithium batteries. The invention described within this patent disclosure proposes at least to assemble both battery electrodes inside a single porous wafer. There may be numerous advantages of the proposed embodiment which may include at least greatly simplified construction of a cell, increased energy density and power density, elimination of a separator, completely sealed cells, increased safety, and many more advantages and improvements over prior arts.

In detail, an embodiment, which may be combined with any other embodiment, may include at least a one-wafer battery. The complete lithium metal battery or other battery type may be fabricated inside a single porous silicon wafer, with cylindrical pores going through the wafer. Each wafer may contain hundreds of thousands of pores and each pore may be a single battery, while all single battery pores may be connected in parallel into a complete battery. One end of the cylinder, i.e., pore may be an anode and the other end may be a cathode, with electrolyte in between.

An additional embodiment, which may be combined with any other embodiment, may include voltage enhancement by internal field. In one-wafer battery the ends of the pores may be metalized while the middle of the pores may be not. The middle of the pores may be passivated with suitable coating to prevent contact of lithium with silicon. This also separates the two sides electrically and enables battery performance. In between the two electrodes, i.e., the two sides, a p-n-junction may be built in silicon and may be located approximately between the anode and the cathode. The n-side of the junction may be on the cathode side of the cell. During the discharge when the electrons may be travelling through the external circuit powering the load and the p-n-junction field may be contributing to this electron movement towards the anode current collector. The built-in voltage may be approximately 0.7V and this may be a significant driving force for additional movement of electrons.

An additional embodiment, which may be combined with any other embodiment, may include metal paste contacts. The one-wafer battery with p-n-junction may be completely sealed with the final process of metallization on each side of the wafer. The metallic contacts may be accomplished using a metal paste with a solvent “vehicle”. The typical composition of the metal paste may include silver metal, glass frit, cellulose resin, solvent (pine oil and glycol ethers), and rheological modifiers and surfactants. The metal paste may be applied over the whole surface of the wafer and in the process plugs in the pores. After drying to drive the solvent off the paste solidifies making excellent metallic contact. This may be a novel method to accomplish current collection in lithium batteries.

This may be applied wherein a one-wafer battery with a similar principle is used. The silicon may be covered with metal in the electrode areas towards the pore openings and with insulator in the middle of the pores, between the electrodes. This may enhance element capable of “moving” electrons in the direction of the voltage difference during the discharge. This presents an effective addition to electron flow and may aid in charging or discharging abilities.

An additional embodiment, which may be combined with any other embodiment, may include compression molded package. The one-wafer battery with p-n-junction may be previously or currently completely sealed and needs very simple package, i.e., cover. This may be accomplished using a well-known process in the electronic packaging, the compression molding. The process may result in a simple, very thin battery.

In other embodiments, which may be instead of, or combined with other embodiments, the present invention may provide wherein the one-wafer batter with p-n junction is only partially sealed, such as for later processing, connecting or any other reason.

The present invention may provide wherein the package may be extremely durable and protects the one-wafer silicon battery. As such, it may be made of any material which may provide reduced degradation, as well as reduced degradation of the interior structures and materials of the battery.

These packaging structures and processes can include those commonly found in integrated circuit or MEMS packaging. Alternatively, other semiconductor packaging processes can be used, such as film lamination molding or printing molding. In some embodiments, the interior may be isolated from the ambient environment, partially isolated, or isolated in certain respects.

An additional embodiment, which may be combined with any other embodiment, the present invention may include solar charging. For applications where fast charging may be necessary the p-n-junction may be reversed to enable more efficient charging process where electrons may be going into negative electrode. The most important advantage may be the possibility to utilize the p-n-junction like in a solar cell and recharge the battery. For this, the edge of the wafer may be either not covered at all (i.e., only the faces of the wafer may be over-molded) or a thin, transparent layer may cover the edge.

This layer may enable transmission of light into the depletion region of the p-n-junction and production of current that may charge the battery. Additionally, the layer may enable the ability to gather light, or to focus the light to enable the highest possible charge ability, such that the battery may be able to be provided power. This may be provided either by the material itself, the geometry or additional materials embedded in the layer. It is noted that this may be added to any other layer.

The solar charging may provide wherein the process may provide to charge the battery, partially, fully, or provide for instance a top off charge, maintaining charge, or provide mitigation of a load on the battery.

This may then allow such that the relatively small surface area for light penetration may provide small additional current for the battery

In other embodiments, or the same embodiments, additional features may be introduced to enhance the collection of light and can be incorporated in the packaging. These include, but are not limited to: mirrors, reflective materials, photon up conversion materials, etc.

In another embodiment, the present invention may then include a construction where a thin solar PV cell may be wafer bonded to a completed one-wafer battery; or the two-wafer assembly (battery+PV cell) may be packaged using compression molding or other molding or material, wherein the construction allows for the solar PV ability but may still isolate the cell or battery from exposure to ambient, etc.

In some embodiments, which may be combined with any other embodiments, the electrolyte before mentioned and after mentioned may instead be a solid electrolyte.

In some embodiments, which may be combined with any other embodiments, the present invention may provide solid electrolyte instead of liquid electrolyte.

In some embodiments, which may be combined with any other embodiments, the solid electrolyte may include but may be not limited to solid lithium ion conductors. For instance such as Li₂S—P₂S₅, Li₂S—P₂S₅—Li₃PO₄, LISICON or Lithium Superionic Conductor, Li3N, Li_{0.5}La_{0.5}TiO₃, Li₃La₅Ta₂O₁₂, Li₁₀GeP₂S₁₂.

In this embodiment, which may be instead of or combined with any other embodiment, the solid electrolyte may be applied using several different physical vapor deposition and chemical vapor deposition methods known to those experienced in the field. There are currently several known solid electrolyte materials for lithium batteries: Li₂S—P₂S₅, Li₂S—P₂S₅—Li₃PO₄, LISICON, Li₃N, Li_{0.5}La_{0.5}TiO₃, Li₃La₅Ta₂O₁₂, or Li₁₀GeP₂S₁₂ for instance. In an embodiment, after solid electrolyte fills part of the pore in the middle, the next step may be to deposit cathode material. This process may be also done using physical vapor deposition or other processes as well. The cathode material can be LiCoO₂, Mn₂O₄FePO₄, or some combination may be present after cathode deposition may be completed, among others.

In some embodiments, which may be combined with any other embodiments the solid electrolyte can be applied using sputtering deposition. For instance, by placing the open end of the pores in a wafer in the path of the sputtering stream in a deposition chamber.

The method, apparatus or system of this embodiment may provide where gaseous plasma may be first created and the generated ions are ejected from a source solid electrolyte material, i.e., source or target. The ions that hit the source electrolyte material may be ejected as neutral particles and travel in a straight line towards the open pores of a silicon wafer. A thin layer of electrolyte may form over the walls of a silicon wafer and establish connection with the metal layer already deposited. A large 3-phase boundary may be created along the pore walls. Because the pores are microscopic it may be possible that the electrolyte material sputtered may eventually deposit to close the pore off.

It is noted that the processes described may prevent the deposition of the cathode material deep into a pore and confine it to the cathode side of the pore, which may prevent electrical shorts. As a second benefit, the solid membrane may also act as a separator during the operation of a battery and during charging process prevent propagation of lithium dendrites, which potentially can occur from cathode to anode and of which may cause shorts.

In some embodiments, which may be combined with any other embodiments, an embodiment with a two-wafer cell, with separated electrodes may include wherein the openings of the pores in wafers that face the separator and each other may be passivated with a non-conductive coating to prevent build-up of dendrites on the electrode surfaces facing each other.

It is noted that it is possible only the opposite sides of the wafers are covered with conductive coating and the coating extends into the first part of the pores. In case of dendrite build-up on those surfaces or inside the pores the dendrites will keep bouncing inside the pores and may not protrude all the way out and towards the separator, which could lead to causing an electrical short with the opposite electrode.

Although the present embodiments have been described with reference to specific example embodiments, it may be evident that various modifications and changes may be made to these embodiments without departing from the broader spirit and scope of the various embodiments. It should be understood by one of ordinary skill in the art that the terms describing processes, products, elements, or methods may be industry terms and may refer to similar alternatives. In addition, the components shown in the figures, their connections, couples, and relationships, and their functions, may be meant to be exemplary only, and may be not meant to limit the embodiments described herein.

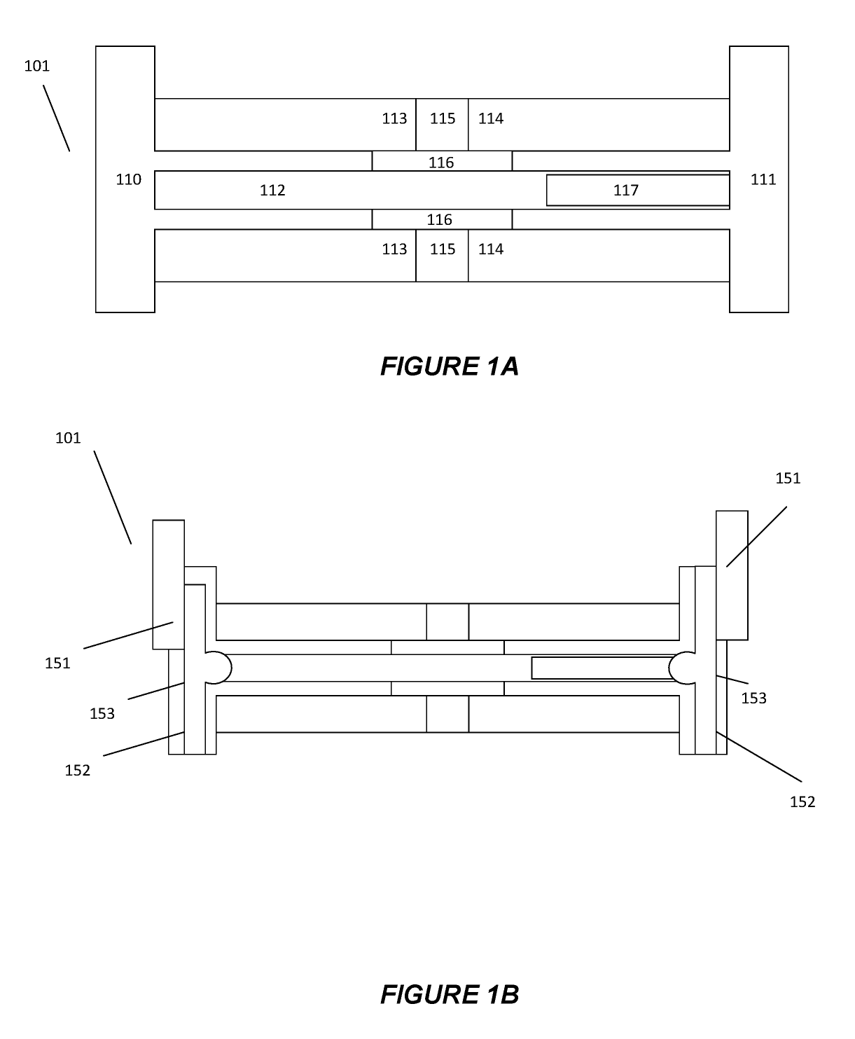

FIGS. 1A and 1B may be a cross-section view of one example embodiment of one pore in a complete “one-wafer battery”.

FIGS. 1A and 1B then describe wherein an enhancement of the performance may be proposed by incorporating a p-n-junction in this one-wafer battery. This creates an electrical field that enhances transport of electrons towards the electrode current collector and improves performance by adding an additional voltage to the battery during the discharge.

FIG. 1A showed such a pore 101, which includes structures 113 and 114 creating the power, wherein structures 113 can include n-type contacts and structures 114 can include p-type structures 114 at the junction areas 115 which creates a passivation area 116 inside the pore. It is noted that the junction areas 115 can be depletion zones. Within each pore can be a liquid electrolyte 112 as well as material 117, of which may be LiCoO₂ which may be a cathode active mass which starts depositing inside the pore. It is noted that within the pore can be anodic metallization area 110 and cathodic metallization area 111.

FIG. 1B shows a similar pore as FIG. 1A, wherein additionally includes contacts 151, wherein may be connected to a bus bar 152 and contacts 153 such that protrude into the pore, such that electrical current can be conducted form the pores. It is also noted that FIG. 1B shows that through the bus bar and contacts, any plurality of pores can be stacked or otherwise grouped, such as wherein many pores are in a matrix as mentioned elsewhere.

It is noted that in some embodiments, the present invention may be provided in instances where stacking may be provided, or wherein there may be more than one wafer. It is appreciated that the processes, methods, apparatuses and symptoms, of which are innovative and ingenious may be applied to as such.

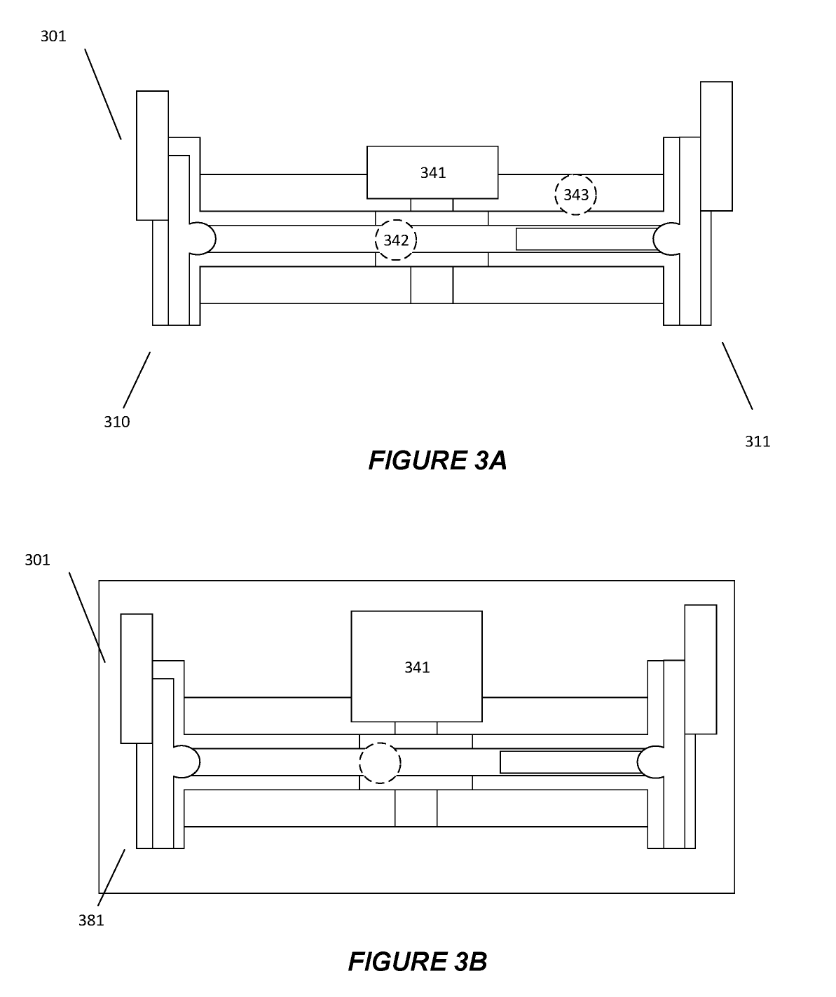

FIG. 2 may be a cross-section view of one example embodiment of a compression molded package of the one-wafer batter with one pore.

FIG. 2 then describes wherein the one-wafer battery concept may enable a completely new battery packaging. Instead of assembling a pouch cell the “one-wafer battery” may be already completely sealed and can be completed by simple compression molding with a plastic compound as customary in the electronic device packaging. This may lead to extremely thin package and elimination of the expensive assembly components and processes used in traditional cylindrical cell or pouch cell battery manufacturing. It may also represent for the first time a completely new battery technology that resembles in all aspects an electronic device fabricated using semiconductor and integrated circuit technology.

The battery may be packaged by plastic compression molding process very well known in the semiconductor industry and those skilled in the art. The mold compound may be typically an epoxy resin, but many different formulations exist that may all be suitable for this application.

In some embodiments, the process involves dipping the “one-wafer battery” into the melted mold compound and then curing the mold. The thickness of the molded package can be controlled (<100 μm). When the mold compound may be carefully selected, the stress on the wafer may be minimized.

This can be depicted in FIG. 2, wherein the pores 201, of which are similar or the same as FIGS. 1A and 1B and other embodiments are sealed in a compression molding 281, such as plastic over molding.

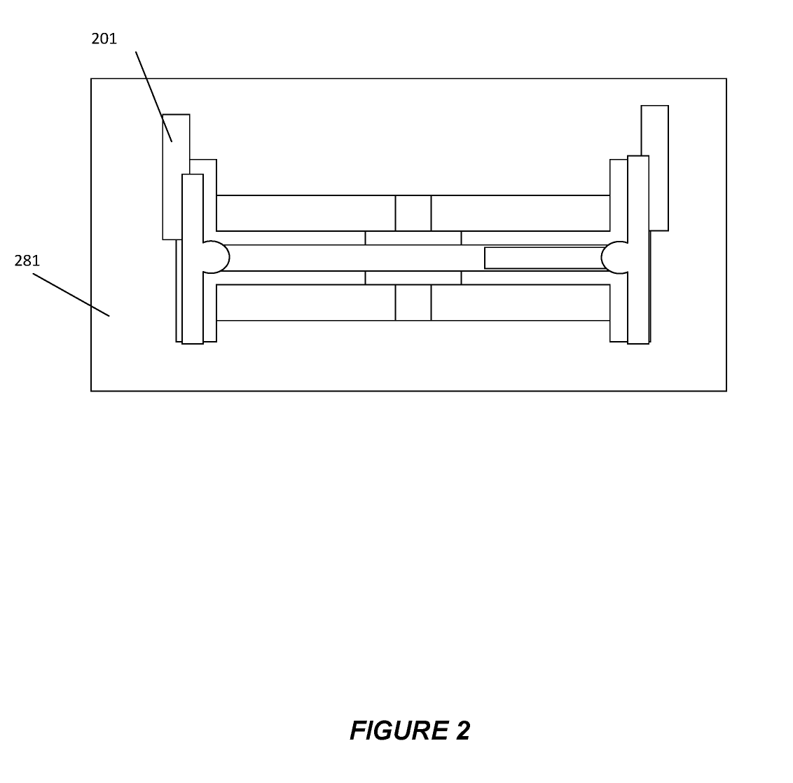

FIGS. 3A and 3B may be a cross-section view of one example embodiment of a battery with transparent window and depiction of the photovoltaic effect for performance enhancement.

FIG. 3 then describes wherein another advantage of the built-in p-n-junction in this battery may be in the possibility to utilize the photovoltaic effect in silicon and capture the sunlight to further improve the battery performance, as the photo current may be adding to the overall battery current. This can be especially utilized in cases where little charge may be left in the battery and it can be enhanced by the photovoltaic current.

As seen in FIG. 3A, with pore 301, this may be wherein light enters through a transparent window 341, such that light enters into the pore. This can cause then the movement of electrons 342 in the direction of the voltage difference (to the cathode side 310), such that an additional potential difference and current is created within the pore. It is noted that side 311 is the anode side.

FIG. 3B describes wherein pores 301 include wherein the compression molding or package 381 may also open the opportunity to include transparent windows 341 on the side of the wafer while over molding the whole device. Incorporation of the transparent window enables the utilization of the photovoltaic effect in silicon, such that photons can travel through the window. It is noted that the lens may be one or two lenses, either a single lens through the package, and through the pores, or one lens separately through the package, and another though the pores. It is noted that any number of intermediary lenses may also be included. Additionally, there may be any plurality of holes 343 in the substrate to aid in function as one in the art would intend for a purpose.

The electrons may be also formed in the middle of the cell where the depletion zone of the p-n-junction creates a voltage difference of about 0.7 V or any other voltage difference. This may be effectively a diode or provide a similar characteristic. During the discharge, the “built-in” voltage element in the p-n-junction may be forward-biased. This electrical field sweeps all electrons in the vicinity and conducts them towards the n-type side electrical contacts. This process effectively increases the rate of oxidation of lithium (Li-->Li++e−) through the effects of the electrical field. It may be conceivable and it can be envisioned that the “built in” voltage element of the p-n-junction may be connected in series with the lithium battery voltage. Hence, the total battery voltage may be expected to increase and electron flow to improve by the process.

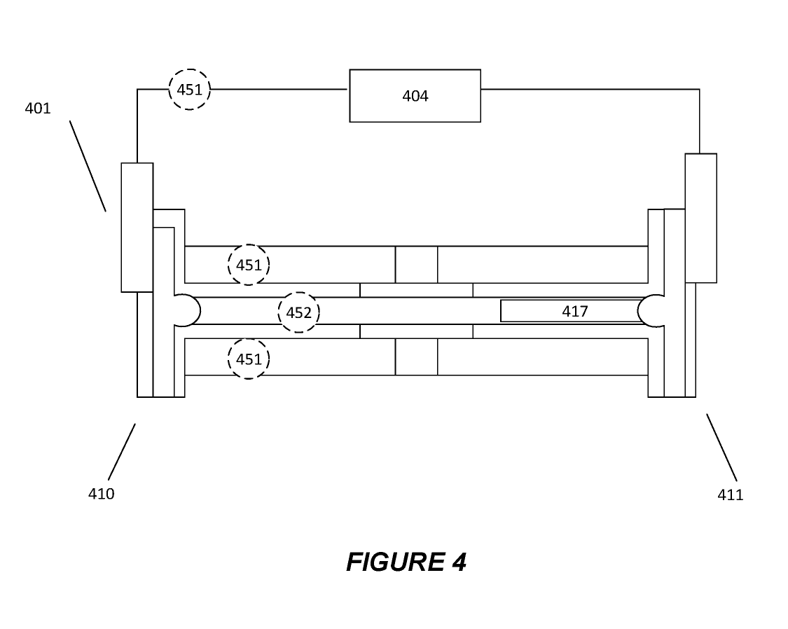

The movement of charge in “one-wafer battery” may be depicted in FIG. 4 below. During the opposite process of the battery charging, the electrons may be “pushed” into the negative electrode by means of a power supply. The p-n-junction in this case would be “reverse-biased” and would resist the influx of electrons into the silicon part of the cells, i.e., the walls of the cylindrical pores. However, this may be not expected to create any negative effects since the breakdown voltage of the p-n-junction diode may be in the excess of 14 V. It is noted that in other systems, the voltage may vary depending on design and construction, as well as intended use.

During the charging process the electrons coming into the negative electrode (i.e., lithium electrode) may simply travel through the electrical conductors (from the tab to “face metal”, to metallic coating inside the pores) and the silicon surrounding the pores may simply be “seen” by the electrical current of electrons as an insulator. Nothing would be different as if the silicon was not there at all and this may be the key advantage of using semiconductor properties of silicon to construct the battery.

FIG. 4 may be a cross-section view of one example embodiment of the movement of charge (e− and Li+) in the discharge process of the one wafer battery.

FIG. 4 then describes wherein the process can also be used to charge the battery in the absence of a power supply, but in this case the p-n-junction may have to be reversed. This would be done for the applications where charging may be more important or where faster charging may be required. The substrate for the lithium metal battery may be porous silicon with thickness of, but not limited to, 100-400 μm and pore diameter of, but not limited to, 1-20 μm. It has been demonstrated previously that this substrate can perform as an electrode for lithium metal battery. In other embodiments, the substrate for the lithium metal battery may be porous silicon with thickness of 100-600 μm and pore diameter of 1-30 μm. It has been demonstrated previously that this substrate can perform as an electrode for lithium metal battery.

While silicon may be the substrate for the electrodes and the rest of the cell it may be not exposed to lithium anywhere in the battery. Instead, silicon may be covered with metal in the electrode areas towards the pore openings and with insulator in the middle of the pores, between the electrodes. This creates a unique structure as the electrodes of a lithium battery may be joined through a special connection that may become an enhancing element capable of “moving” electrons in the direction of the voltage difference during the discharge. This presents an effective addition to electron flow.

During the discharge, the electrons travel through the external circuit, as a result of a potential difference, from anode to cathode and power the load. This movement of the negative charge takes place in the metallic parts of the cell: metallic coating inside the pores on the anode, metal coating at the face of the wafer on the anode side, anode metal tab, load, cathode metal tab, cathode metal layer, and metallic coating on the cathode side of the pores. At the same time, the positive charge moves as lithium ions (Li+) in the same direction (i.e., from anode to cathode), but through the electrolyte.

FIG. 4 depicts this, wherein pore 301 includes wherein an electrons 451 moves to cathode 410 and to the load 404 through the metal coating on the walls. It is noted that then a lithium ion 452 free in the electrolyte moves to the anode 411 and deposits to stack 417.

During the opposite process of the battery charging, the electrons may be “pushed” into the negative electrode by means of a power supply. The p-n-junction in this case would be “reverse-biased” and would resist the influx of electrons into the silicon part of the cells, i.e., the walls of the cylindrical pores. However, this may be not expected to create any negative effects since the breakdown voltage of the p-n-junction diode may be in the excess of 14 V. During the charging process, the electrons coming into the negative electrode (i.e., lithium electrode) may simply travel through the electrical conductors (from the tab to “face metal”, to metallic coating inside the pores) and the silicon surrounding the pores may simply be “seen” by the electrical current of electrons as an insulator. Nothing would be different as if the silicon was not there at all and this may be the key advantage of using semiconductor properties of silicon to construct the battery.

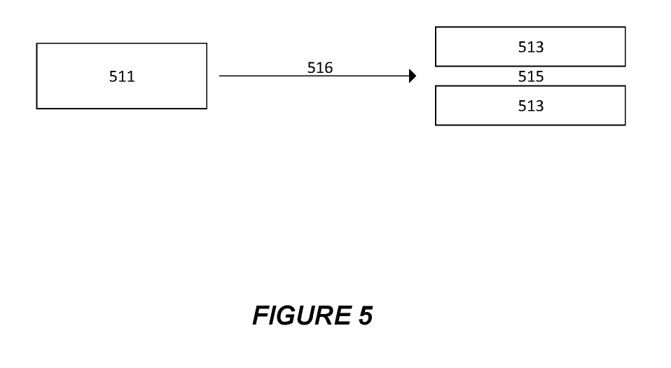

FIG. 5 may be a process diagram of one example embodiment of a p-type silicon wafer to porous silicon.

FIG. 5 then describes wherein the fabrication of one-wafer battery with voltage enhancement the battery fabrication process starts with a p-type silicon wafer. The characteristics of the silicon wafer have been reported before. The wafer may be first etched using a well-known electrochemical etch process or any other method. For instance in an embodiment, deep reactive ion etch (DRIE) may be used. In any process, therein may form cylindrical pores going fully through the wafer, at least a portion, such as a predetermined or actively determined portion, of the way. The shape of the pores may be not limited to cylindrical and it can also be square, rectangular, star shaped, oval, elliptical, conjoined, clover, etc.

FIG. 5 depicts this process, wherein a p-type wafer 511 is electromechanically etched via process 516, such that the wafer includes a pore 515.

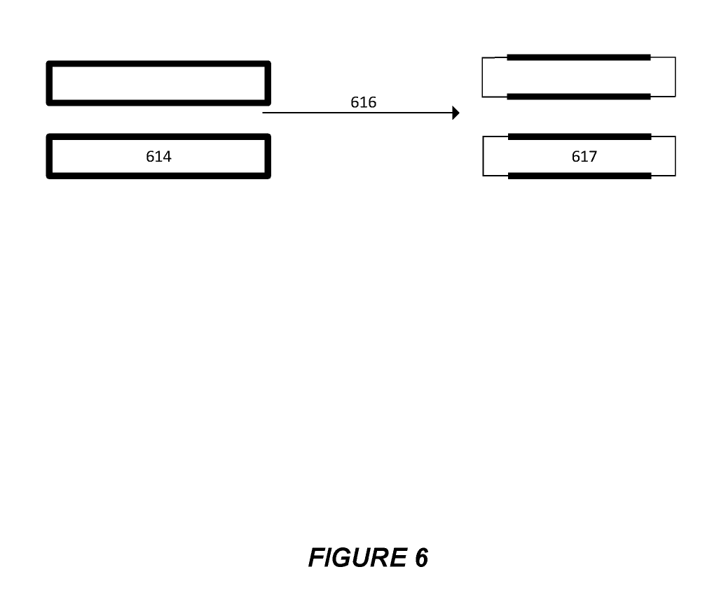

FIG. 6 may be a process diagram and cross-section view of one example embodiment of passivation and partial removal of passivation.

FIG. 6 then describes wherein a porous silicon wafer, such as a p-type wafer 614 may be then treated via process 616 to form a passivating or oxide layer such that substrate 617 is configured.

It is noted that in some embodiments, silicon may be replaced with another material that provides the same or similar properties, wherein efficiency or a characteristic of that particular material may be realized. For instance certain new compound materials may be used which provide a particular characteristic which is more beneficial than silicon.

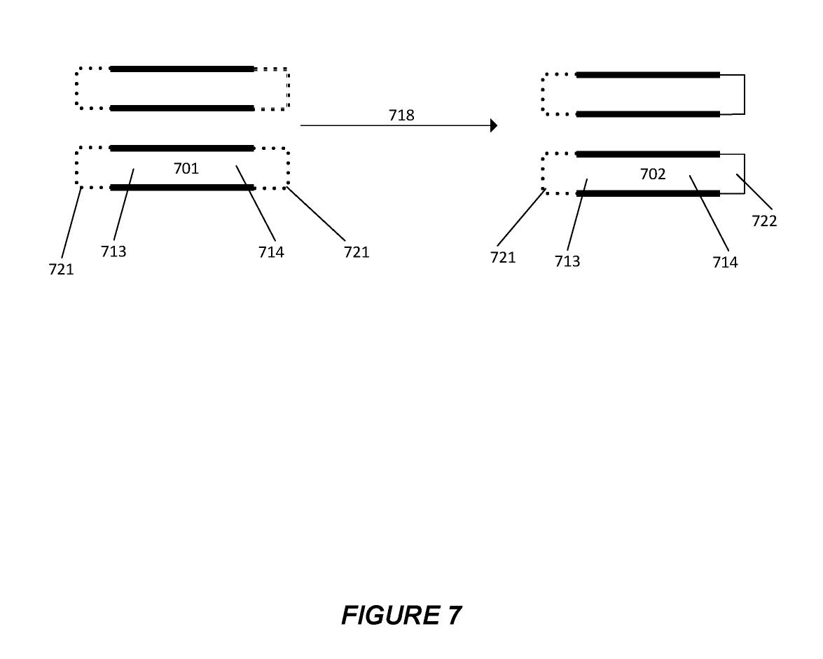

FIG. 7 may be a process schematic and cross-section view of one example embodiment of the present invention.

FIG. 7 then describes wherein the diffusion process 718 may be now applied to introduce n-dopant 721 e.g., phosphorus into silicon wafer 701 such that an n-type area 713 and p-type area 714 exist. The phosphorus dopant may diffuse into silicon only parallel with the length of the pores, so the junction may form between the two faces of the wafer.

In one embodiment, which may be combined with any other embodiment, the junction may be created at a position off-center.

In one embodiment, which may be combined with any other embodiment, the junction may be created at a position off-center wherein the junction may be closer to either side of the wafer. In another embodiment, there may be an asymmetrical junction closer to the cathode end of the wafer to allow for larger length of the pore to be utilized for the performance-limiting cathode material. In another embodiment, there may be an asymmetrical junction closer to the anode end of the wafer. In another embodiment, there may be a symmetrical junction such that may be an equal distance. In other embodiments, the junctions may be offset on any axis as well.

The dopant may be removed on one side (cathode) using a reactive ion etch. The meeting of the dotted and solid lines in FIG. 7 depict the existence of the p-n-junction in the certain area of the wafer, but does not indicate the depth of the junction, which may be much deeper and reaches the middle of the wafer.

This reactive ion etch process 718 can create then wherein the dopant only stays in area 721 and not area 722.

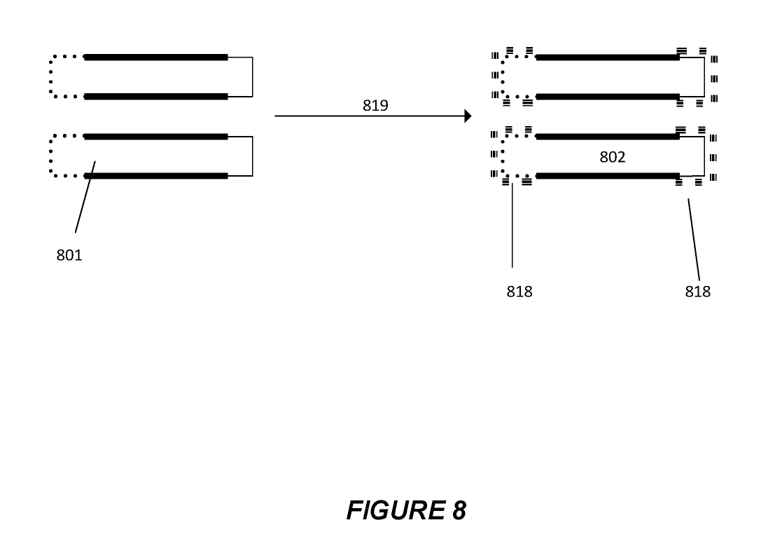

FIG. 8 may be a process schematic and cross-section view of one example embodiment of metallization of the pores and the wafer face.

FIG. 8 then describes wherein a metallization may be then applied from each side of the wafer and adjusted not to reach all the way through the pores, but rather to cover only approximately the first third of the pore length from each side. This can be accomplished by purposely applying metallization from both sides of the wafer while not using the metal deposition techniques that provide deep coverage.

FIG. 8 shows wherein the embodiment wafer 801, similar to other FIG. 7 can use process 819, wherein then such that then a metallization layer 818 is applied as described to the wafer 802 is created.

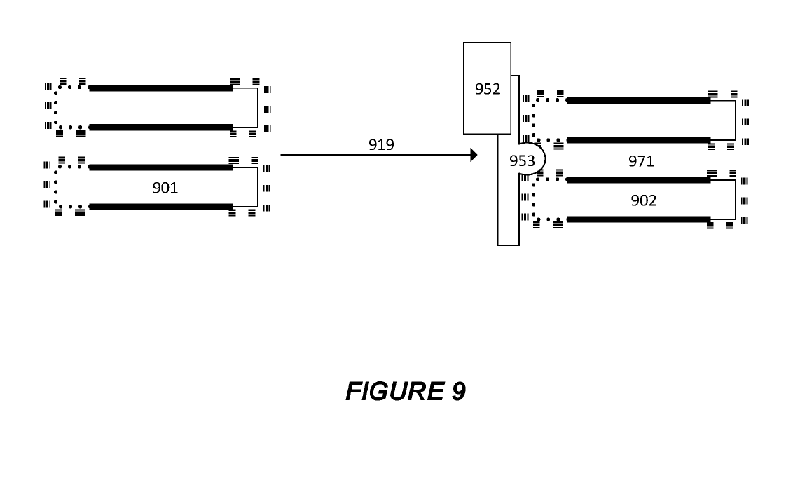

FIG. 9 may be a process schematic and cross-section view of one example embodiment of a partial electrolyte fill.

FIG. 9 then describes wherein the anode side metallization may be next in processing. A metal paste printing may be used to deposit a layer of metal on the face of the wafer. In this process, the paste may be applied to the whole surface and the openings of the pores on the anode side may be covered; the pores may be effectively plugged on that side of the wafer. This may be a very simple process, which may be very well known in the semiconductor manufacturing and in the solar PV industry.

The paste may consist of a metal (typically silver), glass frit, cellulose resin, solvent, and other additives. The exact composition of the paste may be known by those experienced in the field. However, this process represents a true novelty for the battery assembly industry.

The paste may be then dried to remove the solvent, typically in a two-stage process, and it solidifies making a good electrical contact with the metallic layer inside the pores. A metal tab, which may later be the battery contact, may be applied during the process of paste cure to ensure good contact. As the next step, a vacuum may be drawn on the cell (from the cathode side) and the pores may be partially filled with electrolyte. Because the active material may be introduced into the pores afterward, enough space may be left in the pores.

Depicted in FIG. 9 is wherein wafer 901, similar to the wafer 802 in FIG. 8, is via process 919 introduced a plug 953, with an integral or separate bus bar as well as connector 952 may be formed to plug the pore, such that then an electrolyte 971 can be introduced such that embodiment 902 is formed.

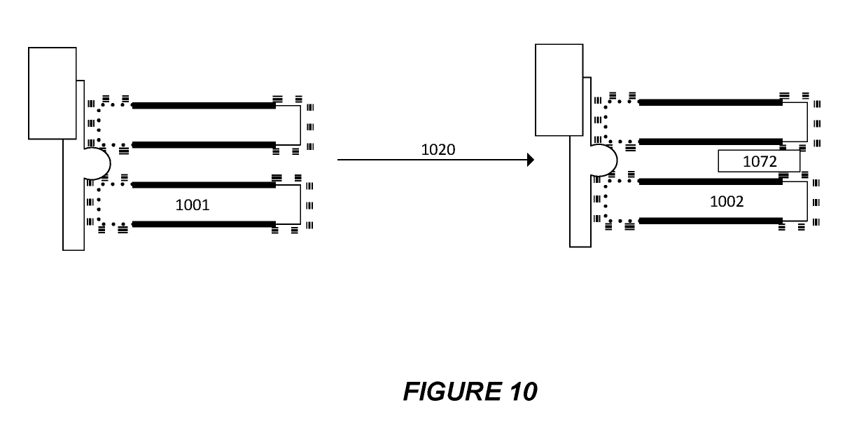

FIG. 10 may be a process schematic and cross-section view of one example embodiment of synthesis of cathode active material inside the pore.

FIG. 10 describes wherein, following the partial electrolyte fill, the cathode active material may be synthesized inside pores on the cathode side. A conformal electrodeposition combined with hydrothermal step may be used. This method may be described in detail in another patent. As the reaction progresses the cathode active mass (e.g., LiCoO₂) starts depositing (i.e., deposits) at the boundary with the electrolyte while slowly replacing the electrolyte from deeper parts of the pore; hence pushing the electrolyte towards the pore opening. When the deposition may be finished, the LiCoO₂ may be completely immersed in the electrolyte and the pore may be nearly full.

Depicted in FIG. 10 is wherein wafer 1001, similar to the wafer 902 in FIG. 9, is via process 1020 introduced a cathode active material as described, such that embodiment 1002 is formed.

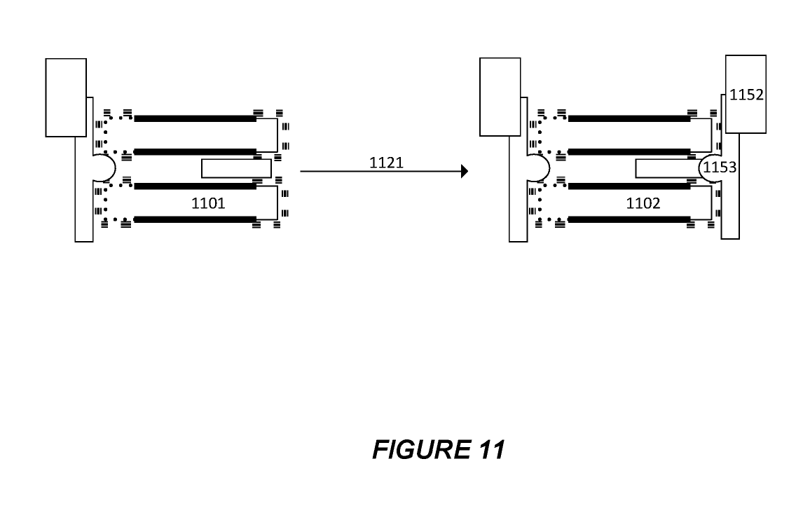

FIG. 11 may be a cross-section view of one example embodiment of metallization of the cathode side.

FIG. 11 describes wherein, the pores on the cathode side of the wafer may be now ready to be closed using the same process as it was for the anode. The metal paste may be applied over the whole surface of the wafer filling slightly into the pore. The metal paste composition might be different from that used on the cathode side. The formulation may depend on the possible interaction with the cathode active material and the electrolyte. A metal tab may be applied during the process of metal paste solidification.

Depicted in FIG. 11 is wherein wafer 1101, similar to the wafer 1002 in FIG. 10, is via process 1021 plugged as described, wherein includes plug, and possible connected bus bar 1153 and possible connector 1152, such that embodiment 1102 is formed.

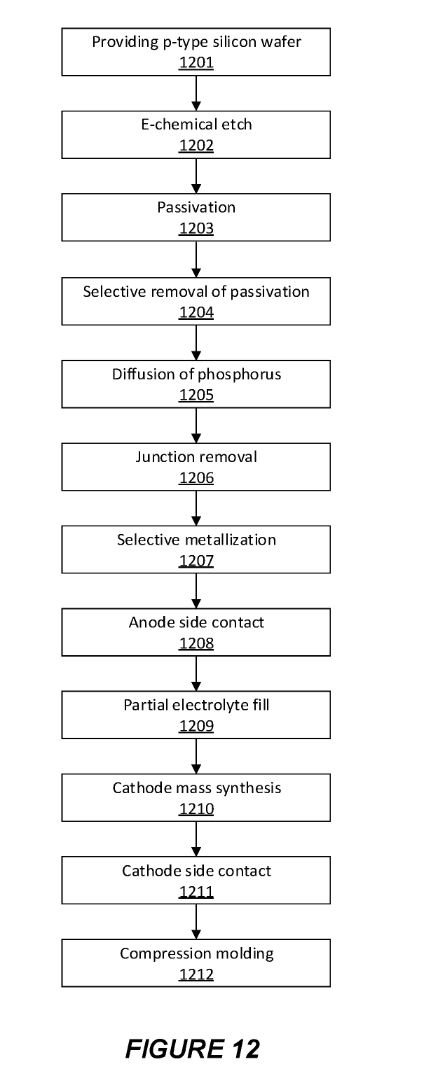

FIG. 12 may be a process diagram of one example embodiment of an overview of the fabrication of the present invention.

FIG. 12 describes wherein, the “one-wafer battery” may be completely sealed and ready for use. These may include at least a step 1201 having a p-type silicon wafer, step 1202 using a e-chemical etch, step 1203 using passivation, step 1204 using a selective remove procedure of passivation, step 1205 diffusing phosphorous, step 1206 junction removal, step 1207 selective materialization, step 1208 anode side contact, step 1209 partial electrolyte fill, step 1210 cathode mass synthesis, step 1211 cathode side contact and step 1212 compression molding. In the next steps the electrical battery formation may be made according to methods very well known in the art as well as having other steps.

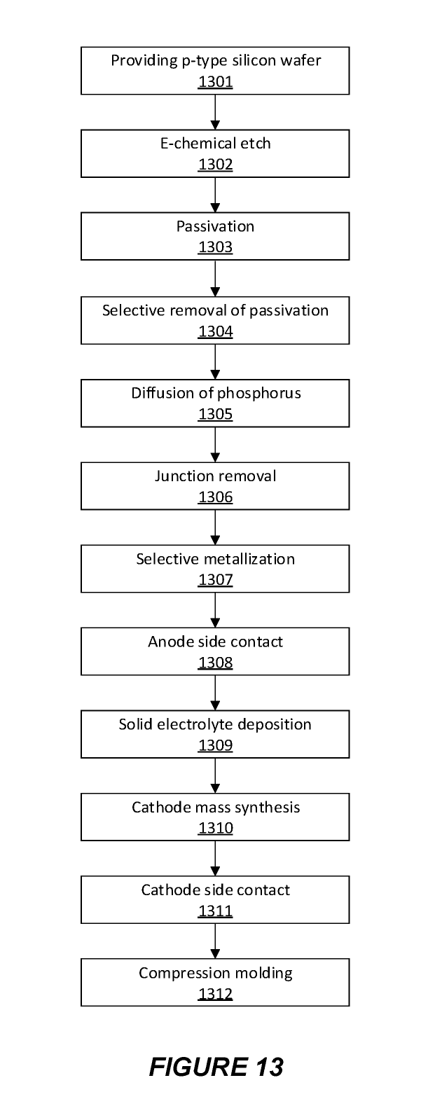

FIG. 13 may be a process diagram of one example embodiment of an overview of the fabrication of the present invention.

FIG. 13 may provide a similar embodiment tot that aforementioned in FIG. 12, but wherein alternatively, step 1309 instead of 1209 partial electrolyte fill may be replaced with a process of applying a solid electrolyte into the pores on the anode side.

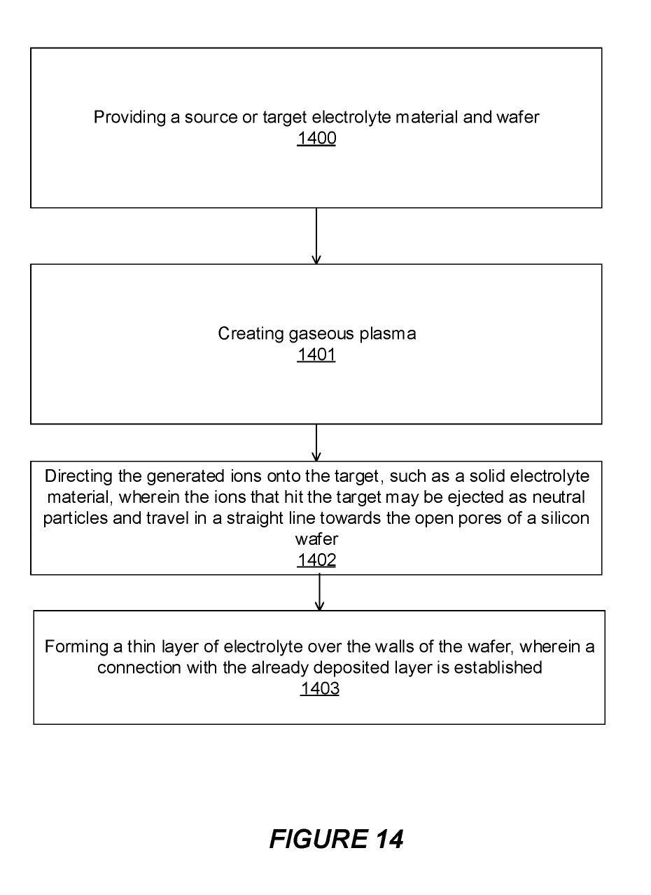

FIG. 14 may be a process diagram of one example embodiment of an overview of the fabrication of the present invention.

FIG. 14 provides at least process 1400 wherein at least providing a source or target electrolyte material and wafer. It is noted that the source or target may be interchangeable in the before described descriptions and later described descriptions, depending on the process, notably the preferred embodiments, is wherein the electrolyte is a target source, wherein the plasma is targeted at the electrolyte, and wherein then s provided a s a source of materials. Therein, the present invention provides further, process 1401 wherein at least creating gaseous plasma, process 1402 wherein at least directing the generated ions onto the target, such as a solid electrolyte material, wherein the ions that hit the target may be ejected as neutral particles and travel in a straight line towards the open pores of a silicon wafer, and process 1403 wherein at least forming for instance by deposition or another known process of which has been described or wherein one skilled in the art would consider, a thin layer of electrolyte over the walls of the wafer, wherein a connection with the already deposited layer may be established.

It is noted that battery may then consist of a single wafer with pores, which are respectively created such that each pore includes an anode and cathode. There also may be an electrolyte, within the volume between and within the wafers. The wafers may include hundreds, thousands or more pores per square centimeter, depending on the application or embodiment, wherein then when the pores create battery cells of any number of cathode and anode pores on a single wafer, or wherein many of these wafers can be packaged together. It is noted that in other disclosures the same concept of a porous wafer battery can be described with an innovative two-wafer design, as applicable to this invention. This may include wherein the anode and cathode are similarly created on their own porous wafer, and then wherein the wafers, with their anode and cathode elements, are proximately configured such that they form an anode-cathode pair between each respective pores, creating a battery. It is noted that this is a noted alternative embodiment that takes many similar elements found herein

A number of embodiments have been described. Nevertheless, it may be understood that various modifications may be made without departing from the spirit and scope of the claimed invention. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments may be within the scope of the following claims.

It may be appreciated that the various systems, methods, and apparatus disclosed herein may be embodied in a machine-readable medium and/or a machine accessible medium compatible with a data processing system (e.g., a computer system) and of which may be in any form including transitory, non-transitory or persistent data systems, as well as may be performed in any order.

The structures and modules in the figures may be shown as distinct and communicating with only a few specific structures and not others. The structures may be merged with each other, may perform overlapping functions, and may communicate with other structures not shown to be connected in the figures. Accordingly, the specification and/or drawings may be regarded in an illustrative rather than a restrictive sense.

What is claimed is:

1. A battery, comprising:
a porous semiconductor material, frame or substrate providing the structure or the support for the battery active materials which include an anode, cathode and electrolyte, wherein:
the anode is made of at least one of the following materials:
lithium metal, lithium silicon, lithium titanate, all combinations of li-ion;
the cathode is made of at least one of the following materials:
cobalt oxide, manganese oxide, nickel-manganese-cobalt oxide, nickel-cobalt-aluminum oxide, iron-phosphate, silicate, etc.

2. A battery, as in claim 1 additionally comprising of:
wherein the semiconductor does not participate in the reaction and remains unchanged during the battery operation.

3. A battery, as in claim 1 additionally comprising of:
wherein the semiconductor provides enhanced performance by being configured in an unchanging, repeatable three-dimensional structure that enables a three-phase boundary for battery reactions, wherein the three-phase boundary signifies the point where the active battery material, electronic conductor and ionic conductor meet.

4. A battery, as in claim 1 additionally comprising of:
wherein the semiconductor is configured to be doped with impurities to increase the electronic conductivity.

5. A battery, as in claim 1 additionally comprising of:
wherein the semiconductor is configured to be doped with impurities to create an electrical field stretching the length of electrode thickness and enhancing the battery reaction.

6. A battery, as in claim 1 additionally comprising of:
wherein the semiconductor is configured with a thicknesses from 50 micrometers to 1000 micrometers, wherein the preferred range the for use in the lithium-based batteries is 60-400 micrometers.

7. A battery, as in claim 1 additionally comprising of:
wherein the semiconductor is configured with one or more pores, such that each pore has the necessary battery active materials to create a pore battery whereby then the pores are in at least one of the following configurations:
the pores span from one end of the semiconductor to the other,
the pores terminate at any length and remain open on one side only.

8. A battery, as in claim 7 additionally comprising of:
wherein the semiconductor contains multiple pores connected electrically in parallel, such that each semiconductor forms a battery made up of connected pore batteries.

9. A battery, as in claim 7 additionally comprising of:
wherein the semiconductor contains multiple pores as separate reaction sites, wherein each site forms a closed system without significant material exchange, but with electrical connection between each other.

10. A battery, as in claim 7 additionally comprising of:
wherein the semiconductor is configured with additional layers of material, wherein the material is:
conductive,
the thicknesses the layers is between 1 nm to 10 micrometers, but preferably between of 20-100 nm.

11. A battery, as in claim 10 additionally comprising of:
wherein the additional layers completely covers the entire surface of a semiconductor including the insides of the pores.

12. A battery, as in claim 10 additionally comprising of:
wherein the additional layers are configured to create diffusion barriers between the battery active materials and the semiconductor.

13. A battery, as in claim 10 additionally comprising of:
wherein the additional layers are configured to enable enhanced adhesion to the semiconductor material and to the subsequent layers.

14. A battery, as in claim 10 additionally comprising of:
wherein the additional layers are configured to conduct an electrical current.

15. A battery, as in claim 10 additionally comprising of:
wherein the additional layers are configured to provide a dielectric barrier layer and prevent electrical current.

16. A battery, as in claim 15 additionally comprising of:
wherein the dielectric barrier layer or a passivation layers are configured to prevent an electrochemical reaction from occurring, to stop at least a reaction that forms lithium deposition and the formation of lithium dendrites on the face of the electrode.

17. A battery, as in claim 1 additionally comprising of:
wherein the battery is formed from one porous semiconductor containing at least one of a conductive layer and a passivation layer;
wherein all the components of the battery are situated within one pore; and each pore is a closed system with no reactant or product exchange with any other pore; but all the pores in the one porous semiconductor are electrically connected in parallel to form a larger battery.

18. A battery, as in claim 1 additionally comprising of:
wherein the battery is formed from two porous semiconductors containing passivation layers on one side; and assembled into a battery cell by orienting the passivation layers to face each other and therefore accomplishing separator-less construction.

19. A battery, as in claim 7 additionally comprising of:
wherein non-electrically conductive materials are configured in the middle of a pore and metalized materials are at the sides of the pores.

20. A battery, as in claim 7 additionally comprising of:
wherein the semiconductor is doped with impurities to create p-type or n-type material and whereby one p-type material is on one side of a pore and n-type material is on the other side of the pore; and whereby a pn junction is formed between the two types of material.

21. A battery, as in claim 7 additionally comprising of:
wherein the pores contain pn-junctions, whereby the pn-junction is removed away from the middle or off-center of the pore.

22. A battery, as in claim 7 additionally comprising of:
wherein the pores contain pn-junctions; and whereby the pn-junctions form an electrical field based on the junction built-in voltage, and enhance the electrical performance of battery by enhancing the cell voltage.

23. A battery, as in claim 7 additionally comprising of:
wherein the ends of pores are sealed with a metallic layer for conduction; and whereby
wherein the battery is completely sealed and does not require additional packaging.

24. A battery, as in claim 7 additionally comprising of:
wherein the semiconductor is coated on the open sides of the pores, such that it is sealed, wherein the seal is metallic and connected to a metallic tab for electrically connecting the battery to the outside environment.

25. A battery, as in claim 24 additionally comprising of:
wherein the seal and metallic tab is configured using a conductive paste or an ink, whereby the solvent evaporates after the application and leaves a conductive bond.

26. A battery, as in claim 7 additionally comprising of:
wherein the substrate and pores are collectively sealed with metallic layers on the outside; and whereby then the exterior layer is over molded with the plastic material package, such that the battery is sealed to the exterior environment.

27. A battery, as in claim 7 additionally comprising of:
wherein a pn-junction in each respective pore is exposed by a transparent window to create a photovoltaic effect that enhances the performance of a battery and can provide battery charging.
